(19) United States
(12) Patent Application Publication
(10) Pub. No.: US 2015/0344731 A1
(43) Pub. Date: Dec. 3, 2015

(54) RESIN COMPOSITION AND USES OF THE SAME

(71) Applicant: TECH ADVANCE INDUSTRIAL CO., LTD., NEW TAIPEI CITY (TW)

(72) Inventor: Chun-Chih Huang, New Taipei City (TW)

(21) Appl. No.: 14/510,253

(22) Filed: Oct. 9, 2014

(30) Foreign Application Priority Data
Jun. 3, 2014 (TW) 103119196

(51) Int. Cl. C09D 179/08; B05D 7/00; C08K 3/36; H05K 1/05; C08G 73/10; C09D 7/12

(52) U.S. Cl. CPC C09D 179/08; C08G 73/10; C09D 7/1216; C08K 3/36; H05K 1/056; B05D 7/00; B05D 2505/50

(57) ABSTRACT

A modified phosphorus-containing unsaturated polyester of Formula I is provided:

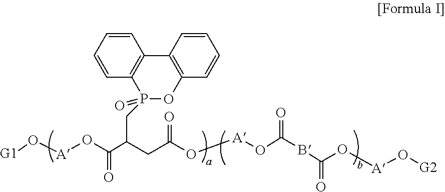

wherein each A′ is independently a residue of a diol or polyol, B′ is a residue of a saturated or unsaturated anhydride or acid, G1 and G2 are independently hydrogen or a residue of an isocyanate acrylate-based compound or isocyanate silicon-containing compound, with the proviso that G1 and G2 are not both hydrogen; and wherein a is an integer of 1 to 30, b is an integer of 1 to 30, and the modified phosphorus-containing unsaturated polyester has an OH value of 50 to 200.

### CLAIM FOR PRIORITY

This application claims the benefit of Taiwan Patent Application No. 103119196 filed on Jun. 3, 2014, the subject matters of which are incorporated herein by reference.

### CROSS-REFERENCES TO RELATED APPLICATIONS

Not applicable.

### BACKGROUND

1. Field of the Invention

The present invention relates to a resin composition and uses of the same.

Specifically, the present invention relates to a resin composition useful for manufacturing a laminate without a reinforcing material, as well as a prepreg and laminate prepared using the same.

2. Descriptions of the Related Art

Printed circuit boards (PCBs) are circuit substrates for electronic devices. PCBs are composed of an insulating material with conductive wirings. In general, when manufacturing an electronic device with a printed circuit board, various electronic elements, including integrated circuits, transistors, diodes, passive elements (e.g., a resistor, a capacitor, a connector etc.), will be mounted on the printed circuit board and electrically connected by conducting wires to make them become active and allow the transmission of electrical signal connections. Hence, a printed circuit board is a platform which connects each of the mounted electronic elements.

For high-speed signal use, a printed circuit board must have alternating-current impedance control and high frequency transmission ability, and must be capable of reducing unnecessary radiation (EMI). Usually, the printed circuit board should be made of an insulating material with a low dielectric coefficient and low attenuation rate to ensure the quality of signal transmission. In addition, the density of elements on circuit boards is continually increased due to the micromation and array arrangement of electronic elements. With the appearances of the packaging ways of ball grid arrays (BGA), chip scale packages (CSP), and direct chip attachments (DCA) etc., printed circuit boards have been developed into an unprecedented high-density level. The technology of manufacturing such circuit boards is called “High Density Interconnection Technology (HDI technology)” as named by the Institute for Interconnecting and Packaging Electronic Circuits (IPC) in America. Among the circuit board industry, the boards manufactured by such technology are called “HDI board,” high-density interconnection printed circuit board, or abbreviated to “high-density circuit board”.

HDI technology utilizes mainly blind and buried micro-via technology to prepare a printed circuit board with a high-density wiring line distribution. The largest differences between HDI technology and other conventional method for manufacturing a circuit board lies in their drilling method. HDI technology employs a non-mechanical drilling method to form vias, such as a laser via method. In general, HDI technology is manufactured by using a build up method. The more the build up time, the higher the technical level needs. Basically, a normal HDI board may be manufactured by performing the build up technology once, while a high-order HDI board must be manufactured by performing the build up technology twice or more along with other advanced technologies such as electroplating via filling, via stacking, direct laser drilling etc.

A resin raw material for preparing HDI board must be suitable for a laser drilling process and have low dielectric characteristics and high size stability. To reduce the thickness of HDI board, the resin raw material is suitable for coreless board technology for preparing a HDI board with no reinforcing material (e.g., a glass fiber cloth). A commonly used resin raw material for manufacturing an HDI board is ABF epoxy resin available from Ajinomoto Co., Inc., Japan. However, because the ABF epoxy resin's thermal resistance is low (its glass transition temperature (Tg) is lower than 180° C.), an additional flame retardant will be necessary in practical use. Furthermore, the ABF epoxy resin also requires a filler to ensure the size stability of the prepared printed circuit board. The said additives not only increase the production cost, but also adversely influence the properties of the printed circuit board, e.g., the drilling quality and the moisture resistance.

TW 1398465 discloses a resin material, which is a modified bismaleimide resin. The modified bismaleimide resin has a good electrical insulation property and flame retardancy and is therefore quite suitable useful for the manufacture of HDI board, especially an HDI board with no reinforced material. However, the properties of the resin material and the board prepared therefrom still need to be improved. For example, to benefit the storage of the resin material, the molecular weight of the polymer contained in the resin material must be controlled and the solvent of the resin material must be screened. The chemical resistance (e.g., the resistance to etching agent), toughness and size stability of the prepared board should be further improved.

### SUMMARY

An objective of the present invention is to provide a resin composition, which is a stable solution containing a modified bismaleimide resin and is prepared by the following steps:

(a) mixing an amideimide of the following formula A with a bismaleimide of the following formula B in a solvent to provide a reaction solution;

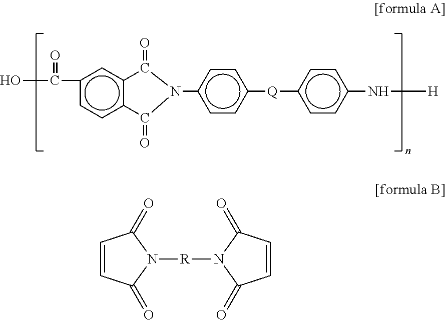

wherein, Q is —CH₂—, —C(CH₃)₂, O, S, SO₂— or not existent; n is an integer of 1 to 100; R is —(CH₂)₂—, —(CH₂)₆—, —(CH₂)₈—, —(CH₂)₁₂—, —CH₂—C(CH₃)₂—CH₂—CH(CH₃)—CH₂—CH₂—,

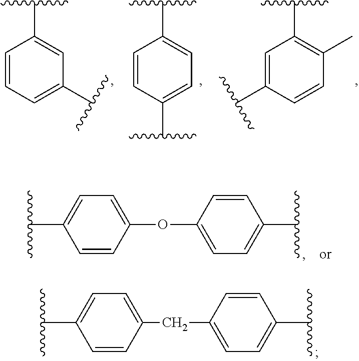

and the weight ratio of the amount of the bismaleimide of formula B to the amideimide of formula A is about 0.4 to about 2.2;
(b) heating the reaction solution to a first temperature to carry out a reaction for 2 to 4 hours to provide a product solution; and
(c) cooling the product solution to a second temperature to substantially terminate the reaction to obtain a stable solution containing a modified bismaleimide resin,
wherein, the solvent is unreactive to the amideimide of formula A and the bismaleimide of formula B; the first temperature is higher than the temperature required for reacting the amideimide of formula A with the bismaleimide of formula B and lower than the boiling point of the solvent; the second temperature is lower than the temperature required for reacting the amideimide of formula A with the bismaleimide of formula B; and the molecular weight of the modified bismaleimide resin is about 120,000 to about 700,000.

Another objective of the present invention is to provide a prepreg, which is obtained by coating the said resin composition on a substrate and drying the coated resin composition to form the prepreg on the substrate.

Yet another objective of the present invention is to provide a laminate, which comprises a synthetic layer and a metal layer, wherein the synthetic layer is made from the said prepreg.

To render the above objectives, technical features and advantages of the present invention more apparent, the present invention will be described in detail with reference to some embodiments hereinafter.

### BRIEF DESCRIPTION OF THE DRAWINGS

Not applicable.

### DETAILED DESCRIPTION

Hereinafter, some embodiments of the present invention will be described in detail with reference to the appended drawings. However, without departing from the spirit of the present invention, the present invention may be embodied in various embodiments and should not be limited to the embodiments described in the specification and drawings. Furthermore, for clarity, the size of each element and each area may be exaggerated in the appended drawings and not depicted in actual proportion. Unless it is additionally explained, the expressions “a,” “the,” or the like recited in the specification of the present invention (especially in the claims) should include both the singular and the plural forms. Furthermore, unless it is additionally explained, while describing the constituents in the solution, mixture and composition in the specification, the amount of each constituent is measured based on the solid content, i.e., regardless of the weight of the solvent.

The technical features of the present invention lie in reacting amideimide and bismaleimide at a specific ratio under a specific reaction condition to prepare a stable solution containing a modified bismaleimide resin. The stable solution is served as a resin composition for preparing prepregs and laminates. The resin composition of the present invention may be stored for a long period of time without a significant precipitation phenomenon, because the modified bismaleimide resin contained in the resin composition has an excellent compatibility with the solvent of the resin composition. Furthermore, the prepreg prepared from the resin composition is provided with outstanding chemical resistance and ductility and can be preserved at room temperature for a long period of time without incurring any damages in its properties. The laminate prepared by the prepreg has outstanding physicochemical properties (e.g., high glass transition temperature (Tg), good moisture resistance, good size stability, good flame retardance, and good chemical resistance) and electrical properties (e.g., low Df, Dk). The laminate is suitable for a laser drilling process.

Specifically, the resin composition of the present invention is a stable solution containing a modified bismaleimide resin, which is prepared by the following steps:

(a) mixing an amideimide with a bismaleimide in a solvent to provide a reaction solution;
(b) heating the reaction solution to a first temperature to carry out a reaction for 2 to 4 hours to provide a product solution; and
(c) cooling the product solution to a second temperature to substantially terminate the reaction to obtain a stable solution containing a modified bismaleimide resin,
wherein, the solvent is unreactive to the amideimide and the bismaleimide; the first temperature is higher than the temperature required for reacting the amideimide with the bismaleimide and lower than the boiling point of the solvent; the second temperature is lower than the temperature required for reacting the amideimide with the bismaleimide.

In step (a), the amideimide has a structure of the following formula A, and the bismaleimide has a structure of the following formula B.

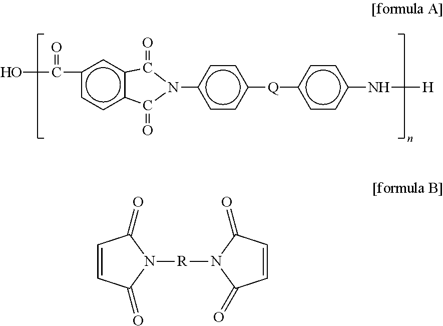

In formulae A and B, Q is —CH₂—, —C(CH₃)₂—, O, S, SO₂— or not existent; n is an integer of 1 to 100; R is —(CH₂)₂—, —(CH₂)₆—, —(CH₂)₈—, —(CH₂)₁₂—, —CH₂—C(CH₃)₂—CH₂—CH(CH₃)—CH₂—CH₂—,

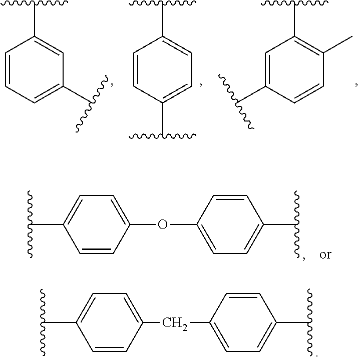

In some embodiments of the present invention, Q is —CH₂— and R is

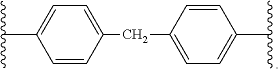 [SMILES: *c1ccc(Cc2ccc(*)cc2)cc1]

It is found that the resin composition of the present invention obtained under a specific mixing ratio of amideimide and bismaleimide is especially suitable for preparing HDI boards since the laminate prepared therefrom has excellent flame retardance (high Tg), size stability (low rate of expansion), adhesive strength, toughness, chemical resistance and electrical properties. Therefore, according to the present invention, in step (a), the weight ratio of the amount of the bismaleimide of formula B to the amideimide of formula A is preferably about 0.4 to about 2.2, and more preferably about 0.8 to about 2.0.

Furthermore, the organic solvent used in step (a) is a solvent which can dissolve but does not react with amideimide and bismaleimide, and is preferred to have a catalytic effect on the reaction. Furthermore, in view of operation convenience, the boiling point of the organic solvent should be at least higher than the maximum operating temperature involved in the preparation of the resin composition of the present invention. The maximum operating temperature is generally around the temperature for the ring-opening polymerization. The purpose of controlling the boiling point is to prevent the solvent from escaping during the operation and thus change the concentration of the first reaction solution, which may incur problems in the subsequent process (e.g., the solution may become too thick to stir) or influence the quality of the prepared solution (e.g., the polymerization degree of the polymer may be non-uniform). Generally, the solvent may be selected from those with a boiling point higher than 130° C. For example, the solvent may be selected from the group consisting of cyclohexanone, acetone, butanone, methyl isobutyl ketone, N,N-dimethyl formamide (DMF), N,N-dimethyl acetamide (DMAc), N-methyl-pyrrolidone (NMP) and combinations thereof. In some embodiments of the present invention, the solvent is a mixture of N-methyl-pyrrolidone (NMP) and N,N-dimethyl formamide (DMF) or a mixture of N-methyl-pyrrolidone (NMP) and N,N-dimethyl acetamide (DMAc). These mixtures have a high compatibility with the modified bismaleimide resin contained in the resin composition. The resin composition can therefore be stored for a longer period of time.

According to the present invention, in step (a), the organic solvent should be used in an amount that can not only dissolve the amideimide and bismaleimide, but also be able to ensure that the polymer produced by the polymerization reaction is stably dissolved/dispersed in the solvent without generating any precipitates. Generally, the amount of the organic solvent is usually at least about 50 parts by weight per 100 parts by weight of the total weight of the amideimide and bismaleimide. For example, the amount of the organic solvent may be about 50 parts by weight to about 150 parts by weight and preferably about 80 parts by weight to about 120 parts by weight, per 100 parts by weight of the total weight of the amideimide and bismaleimide. However, the amount of the organic solvent should not be limited to the amount mentioned above, and persons with ordinary skill in the art can adjust the amount of the organic solvent depending on the needs based on the disclosure of the present specification.

After amideimide and bismaleimide are uniformly dissolved in the organic solvent to form a reaction solution, the reaction solution is heated in step (b) to a first temperature to carry out an addition/polymerization reaction of imide to prepare a stable solution containing a modified bismaleimide resin. The first temperature is at least higher than the temperature required for reacting the amideimide and bismaleimide such that the addition/polymerization reaction could be carried out without using an expensive, environmentally hazardous catalyst. Furthermore, the first temperature should be lower than the boiling point of the solvent to prevent the solvent from escaping during the operation and changing the concentration of the reaction solution, which may result in difficulty conducting subsequent processes or influence the quality of the prepared polymer solution. Generally, the first temperature ranges from about 100° C. to about 160° C., and preferably about 120° C. to about 160° C. In some embodiments of the present invention, the first temperature ranges from about 120° C. to about 140° C. In addition, it is found that the duration time of the reaction at the first temperature should range from about 2 hours to about 4 hours. If the duration time is outside the range, it is impossible to obtain a laminate with both excellent physicochemical properties and electrical properties, especially, if the adhesive strength and chemical resistance of the laminate become unsatisfactory.

Without being restricted by any theories, it is believed that the modified bismaleimide resin obtained by reacting the amideimide of formula A and the bismaleimide of formula B has a structure represented by the following formula I or II:

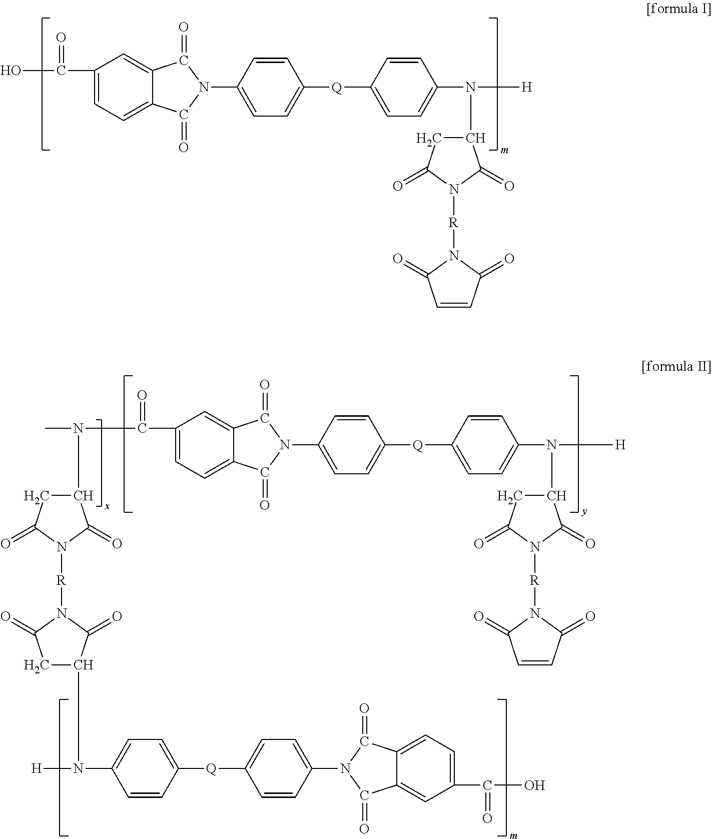

wherein, Q and R are as defined above, 10<m<500, and x+y=m.

In the resin composition of the present invention, the molecular weight of the contained modified bismaleimide resin ranges from about 120,000 to about 700,000. Such molecular weight exactly ensures the prepared product is in a stable solution form and has a proper viscosity for the preparation of prepregs.

The energy required for the heating of the reaction solution in step (b) may be provided by any suitable means. For example, thermal energy (such as a water bath, an oil bath, an electrical heater, and a heat exchanger), radiant energy (such as a UV irradiation and a γ-ray irradiation) or any combinations thereof can be used to raise the temperature to a temperature required for carrying out the addition/polymerization reaction. In addition, to enhance the uniformity of heat transfer and uniformity of reaction, the reaction solution should be stirred during the heating process. After the polymerization reaction is done, a product solution is obtained in step (b). Then, in step (C) the temperature of the product solution is lowered to a second temperature to substantially terminate the polymerization reaction and thus obtain a stable solution, i.e., the resin composition of the present invention. The term “substantially terminate” means that the addition/polymerization reaction between the amideimide and bismaleimide, between the modified bismaleimide resin molecules, and between the modified bismaleimide resin and amideimide or bismaleimide polymer are considerably ceased so that the molecular weight of the formed polymer would not be significantly changed during the predetermined storage period and a precipitate would not be formed. Here, the temperature for terminating the addition/polymerization reaction depends on the species of the applied amideimide and bismaleimide. Theoretically, the second temperature can be controlled to be approximately room temperature, but not limited thereto. Based on the disclosure of the present specification, persons with ordinary skill in the art may choose any suitable second temperature to terminate the addition/polymerization reaction based on their ordinary skill or demands. In addition, there is no special limitation on the means for cooling in step (c). Any suitable operation may be used to lower the temperature. For example, the polymer solution obtained in step (b) may be subjected to a gas atmosphere at room temperature, a water bath at room temperature, or a combination thereof, to lower its temperature to substantially terminate the polymerization reaction.

The resin composition of the present invention may optionally comprise other additives. The additives may be, for example, selected from the group consisting of a hardening promoter, a filler, a dispersing agent, a flexibilizer, a flame retardant and any combinations thereof. The additives may be used alone or in combination. For instance, a Lewis acid or an imidazole compound as a hardening promoter may be added into the resin composition of the present invention to improve the hardening efficacy. If a hardening promoter is used, the amount of the hardening promoter may be selected depending on the user's need. Generally, the amount of the hardening promoter is about 0.01 parts by weight to about 1.5 parts by weight per 100 parts by weight of the total weight of the amideimide and bismaleimide. Also, a filler, for example, selected from the group consisting of silica, glass powder, talcum, kaolin, pryan, mica and combinations thereof, but not limited to, may be added into the resin composition of the present invention to improve the processability, flame retardance, thermal resistance, and moisture resistance of the resin composition. When a filler is used, the amount of the filler may be adjusted depending on the user's need and is generally about 0.01 parts by weight to about 120 parts by weight per 100 parts by weight of the total weight of the amideimide and bismaleimide.

The resin composition of the present invention may be evenly mixed with additives or other constituents by a stirrer, and dissolved and dispersed in a solvent to become varnish for subsequent applications.

The present invention further provides a prepreg, which is obtained by coating the said resin composition on a substrate and drying the coated resin composition to form the prepreg on the substrate. Specifically, the prepreg may be obtained by coating the resin composition of the present invention on a plastic substrate (e.g., a releasing film) or a metal substrate (e.g., a copper foil), and then heating the coated substrate to carry out a further polymerization reaction and remove a majority of solvent to form the prepreg. In some embodiments of the present invention, the heat treatment is carried out at 180° C. for about 2 minutes to about 5 minutes to provide prepregs in a half-hardened state.

The present invention further provides a laminate, which comprises a synthetic layer and a metal layer, wherein the synthetic layer is made from the said prepreg. A plurality of the said prepregs may be superimposed. A metal foil (e.g., copper foil) is superimposed on at least one external surface of the synthetic layer composed by the superimposed prepreg to provide a superimposed object. A hot-pressing operation is carried out onto the superimposed object to provide a laminate. Furthermore, a printed circuit laminate may be prepared by further patterning the metal foil of the laminate.

The present invention will be further illustrated by the embodiments hereinafter, wherein the measuring instruments and methods are described respectively as follows:

[Gel Permeation Chromatography (GPC) Analysis]

The analysis is carried out by using a Gel Permeation Chromatography analyzer (model number: water 600) from Waters Company.

[Infrared Spectrum Analysis]

The analysis is carried out by using a Fourier transform-Infrared Spectrometer (model number: Spectrum 100) from Perkin-Elmer Company.

[Glass Transition Temperature (Tg) Test]

The glass transition temperature (Tg) is measured by a differential scanning calorimetry (DSC) method. The used instrument is a Differential Scanning calorimeter (model number: DCS 7) from Perkin-Elmer Company. The measuring regulations that are used are IPC-TM-650.2.4.25C and 24C testing methods of the Institute for Interconnecting and Packaging Electronic Circuits (IPC).

[Dielectric Constant (Dk) and Dissipation Factor (Df) Measurement]

Dk and Df are measured according to ASTM D150 under an operating frequency of 1 GHz.

[Coefficient of Thermal Expansion Test]

The linear coefficient of thermal expansion of the base surface of the sample and the thermal expansion rate in the thickness direction (Z-axis direction) of the sample are measured by using the thermal expansion analyzer (model: TA 2940) from TA Instrument Company between a temperature gap ranging from about 50° C. to 260° C. (heating rate: 10° C./min), wherein the sample is a laminate with a size of 3 square millimeters.

[Thermal Decomposition Temperature Test]

The thermal decomposition temperature test is carried out by measuring the mass loss of the sample with a thermogravimetric analyzer (TGA). The temperature where the mass loss is up to 5% is regarded as the thermal decomposition temperature.

[Flame Retardance Test]

The flame retardance test is carried out according to UL94V (Vertical Burn), which comprises the burning of a laminate, which is held vertical, using a Bunsen burner to obtain its self-ignition and combustion-supporting properties.

[Toughness Test]

The method for testing the toughness comprises the following steps: laying the laminate on a plane fixture; vertically placing a cross metal jig to come into contact with the surface of the laminate while applying a vertically-applied pressure to the cross metal jig; removing the cross metal jig; and observing the cross trace on the substrate. The laminate without any white embossing lines is regarded as having good toughness. The one with slight white embossing lines is regarded as having normal toughness, and the one with cracks or rupturing one is regarded as having a poor toughness.

[Chemical Resistance Test]

The chemical resistance test is carried out by soaking the laminate in a potassium permanganate solution for 10 minutes and then baking and drying the soaked laminate. The surface gloss of the laminate is checked; the one which is still glossy is regarded as good, while the one with a matte surface at less than 10% area of the surface is regarded as normal.

[Laser Drilling Test]

The laser drilling is carried out by subjecting CO₂ laser with a maximum energy of 200 W onto the laminate, wherein the via diameter is 500 nm. Next, a burr evaluation of the via edge is carried out through an optical microscope; the one with a burr fewer than 5% is evaluated as good, while the one with a burr more than 5% to 25% is evaluated as normal, and the one with burr more than 25% is evaluated as poor.

### EXAMPLE

### Preparation of the Resin Composition

### Example 1

80 g of Amideimide (AI) resin solution (Fu-Pao Chemical Co., model number: AI-35P, corresponding to the amideimide of formula A where Q is —CH₂—, and the amount of the amideimide resin is 28 g), 44.8 g of bismaleimide (BMI, KI Chemical Co., corresponding to the bismaleimide of formula B where R is

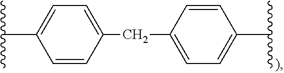 [SMILES: *c1ccc(Cc2ccc(*)cc2)cc1]

52 g of NMP and 18 g of DMAc were added into a 500 ml three-necked glass reactor and uniformly stirred using a two-impeller stir bar at 120-140° C. for 2 hours to carry out a reaction. Thereafter, the product solution was cooled to room temperature in a room temperature environment. A resin composition 1 containing a modified bismaleimide resin according to the present invention was prepared. As shown in Table 1, in this Example, the weight ratio of the amount of the bismaleimide to the amideimide is 1.6, and the ratio of the total amount of bismaleimide and amideimide to the solvent (NMP and DMAc) is 1.04.

### Example 2

The preparation procedures of Example 1 were repeated to prepare resin composition 2, except that the reaction time is 3 hours, as shown in Table 1.

### Example 3

The preparation procedures of Example 1 were repeated to prepare resin composition 3, except that the reaction time is 4 hours, as shown in Table 1.

### Example 4

The preparation procedures of Example 1 were repeated to prepare resin composition 4, except that DMAc is replaced with DMF, as shown in Table 1.

### Example 5

The preparation procedures of Example 1 were repeated to prepare resin composition 5, except that the ratio of the amount of the bismaleimide to the amideimide is 1.0 (the amount of each of the bismaleimide and the amideimide is 35 g) and the solvent is composed of 65 g NMP and 2.31 g DMAc, as shown in Table 1.

### Example 6

The preparation procedures of Example 1 were repeated to prepare resin composition 6, except that the ratio of the amount of the bismaleimide to the amideimide is 2.0 (the amount of the bismaleimide is 52 g and the amount of the amideimide is 26 g) and the solvent is composed of 74.29 g NMP and 0.71 g DMAc, as shown in Table 1.

### Example 7

The preparation procedures of Example 1 were repeated to prepare resin composition 7, except that 0.1 g of silane coupling agent is further added as a dispersing agent and 48.5 g of silicon dioxide is further added as a filler, as shown in Table 1.

### Comparative Example 1

The preparation procedures of Example 1 were repeated to prepare comparative resin composition 1′, except that the reaction time is 1 hour, as shown in Table 1.

### Comparative Example 2

The preparation procedures of Example 1 were repeated to prepare comparative resin composition 2′, except that the reaction time is 5 hours, as shown in Table 1.

### Comparative Example 3

The preparation procedures of Example 1 were repeated to prepare comparative resin composition 3′, except that the amount of the bismaleimide is adjusted to 8.4 g such that the ratio of the amount of the bismaleimide to the amideimide is 0.3, and 52 g of NMP is used alone as the solvent, as shown in Table 1.

### Comparative Example 4

The preparation procedures of Example 1 were repeated to prepare comparative resin composition 4′, except that the ratio of the amount of the bismaleimide to the amideimide is 2.5 (the amount of the bismaleimide is 75 g and the amount of the amideimide is 30 g) and the solvent is composed of 55.71 g NMP and 45.25 g DMAc, as shown in Table 1.

[Preparation of the Prepreg]

The prepreg was prepared using resin compositions 1 to 7 and comparative resin compositions 1′ to 4′, respectively. Those resin compositions were coated on a PI plastic film by a roll coater, respectively. The PI plastic films coated with resin composition were then placed in an oven and dried at 170° C. for 2 to 5 minutes to produce prepregs in a half-hardened state. Prepregs 1 to 7 (corresponding to resin compositions 1 to 7) and comparative prepregs 1′ to 4′, each with a thickness of 0.06 mm were obtained.

[Preparation of the Laminate]

Five pieces of prepregs were superimposed and two sheets of copper foil (1 oz) were respectively superimposed on the two external surfaces of the superimposed prepregs to provide a superimposed object. A hot-pressing operation was performed on each of the prepared objects to provide laminates 1 to 7 (corresponding to prepregs 1 to 7) and comparative laminates 1′ to 4′ (corresponding to comparative prepregs 1′ to 4′), each with a thickness of 0.35 mm. The hot-pressing conditions are as follows: raising the temperature to 200° C. with a heating rate of 2.0° C./min, and hot-pressing for 90 minutes under the full pressure of 15 kg/cm′ (initial pressure is 8 kg/cm′) at 200° C.

The glass transition temperature (Tg), thermal resistance, adhesive strength, dielectric constant (Dk), dissipation factor (Df), coefficient of thermal expansion (al), z-axis expansion percentage, thermal decomposition temperature, flame retardance, toughness, chemical resistance, and laser drilling processing result of laminates 1 to 7 and comparative laminates 1′ to 4′ were analyzed and the results are tabulated in Table 1.

TABLE 1

| | | Resin composition number | | | | | |
|---|---|---|---|---|---|---|---|
| | | resin | resin | resin | resin | resin | resin |
| | unit | composition 1 | composition 2 | composition 3 | composition 4 | composition 5 | composition 6 |
| amideimide | g | 28 | 28 | 28 | 28 | 35 | 26 |
| resin | | | | | | | |
| bismaleimide | g | 44.8 | 44.8 | 44.8 | 44.8 | 35 | 52 |
| resin | | | | | | | |
| 2E4MI | g | 0.73 | 0.73 | 0.73 | 0.73 | 0.77 | 0.78 |
| (hardening | | | | | | | |
| promoter) | | | | | | | |
| DMAc | g | 18 | 18 | 18 | | 2.31 | |
| DMF | g | | | | 18 | | 0.71 |
| NMP | g | 52 | 52 | 52 | 52 | 65 | 74.29 |
| SiO₂ | g | | | | | | |
| silane | g | | | | | | |
| coupling | | | | | | | |
| agent | | | | | | | |
| GPC | | 140000 | 150000 | 150000 | 140000 | 650000 | 125000 |
| gelation time | sec | 270 | 255 | 255 | 270 | 290 | 240 |
| prepreg | | prepreg 1 | prepreg 2 | prepreg 3 | prepreg 4 | prepreg 5 | prepreg 6 |
| number | | | | | | | |
| laminate | | laminate 1 | laminate 2 | laminate 3 | laminate 4 | laminate 5 | laminate 6 |
| number | | | | | | | |
| glass | ° C. | 248 | 265 | 268 | 247 | 236 | 272 |
| transition | | | | | | | |
| temperature | | | | | | | |
| thermal | sec | >180 | >180 | >180 | >180 | >180 | >180 |
| resistance | | | | | | | |
| (288° C.) | | | | | | | |
| adhesive | lbf/in | 6.4 | 6.2 | 6.1 | 6.4 | 6.2 | 6.1 |
| strength | | | | | | | |
| dielectric | GHz | 3.8 | 3.7 | 3.6 | 3.8 | 3.7 | 3.9 |
| constant | | | | | | | |
| dissipation | GHz | 0.010 | 0.011 | 0.011 | 0.010 | 0.012 | 0.012 |
| factor | | | | | | | |
| coefficient of | ppm/° C. | 41 | 40 | 40 | 40 | 39 | 45 |
| thermal | | | | | | | |
| expansion | | | | | | | |
| (α1) | | | | | | | |
| Z-axis | % | 2.4 | 2.3 | 2.3 | 2.4 | 2.4 | 2.5 |
| expansion | | | | | | | |
| percentage | | | | | | | |
| thermal | ° C. | 465 | 450 | 449 | 464 | 435 | 445 |
| decomposition | | | | | | | |
| temperature | | | | | | | |
| UL-94 | sec | 8 | 8 | 7 | 8 | 7 | 9 |
| toughness | appear- | good | good | good | good | good | good |
| | ance | | | | | | |
| chemical | | good | good | good | good | good | good |
| resistance | | | | | | | |
| laser drilling | | good | good | good | good | good | good |
| result | | | | | | | |

| | | Resin composition number | | | | |
|---|---|---|---|---|---|---|
| | | | comparative | comparative | comparative | comparative |
| | | resin | resin | resin | resin | resin |
| | unit | composition 7 | composition 1′ | composition 2′ | composition 3′ | composition 4′ |
| amideimide | g | 28 | 28 | 28 | 28 | 30 |
| resin | | | | | | |
| bismaleimide | g | 44.8 | 44.8 | 44.8 | 8.4 | 75 |
| resin | | | | | | |
| 2E4MI | g | 0.73 | 0.73 | 0.73 | 0.54 | 0.89 |
| (hardening | | | | | | |
| promoter) | | | | | | |
| DMAc | g | 18 | 18 | 18 | | 45.25 |
| DMF | g | | | | | |
| NMP | g | 52 | 52 | 52 | 52 | 55.71 |
| SiO₂ | g | 48.5 | | | | |
| silane | g | 0.1 | | | | |
| coupling | | | | | | |
| agent | | | | | | |
| GPC | | 140000 | 120000 | 150000 | 300000 | 100000 |
| gelation time | sec | 270 | 305 | 195 | 315 | 205 |
| prepreg | | prepreg 7 | comparative | comparative | comparative | comparative |
| number | | | prepreg 1′ | prepreg 2′ | prepreg 3′ | prepreg 4′ |
| laminate | | laminate 7 | comparative | comparative | comparative | comparative |
| number | | | laminate 1′ | laminate 2′ | laminate 3′ | laminate 4′ |
| glass | ° C. | 245 | 207 | 284 | 210 | 265 |
| transition | | | | | | |
| temperature | | | | | | |
| thermal | sec | >180 | >180 | >180 | >180 | >180 |
| resistance | | | | | | |
| (288° C.) | | | | | | |
| adhesive | lbf/in | 6.2 | 5.6 | 5.8 | 5.4 | 6.0 |
| strength | | | | | | |
| dielectric | GHz | 3.9 | 3.9 | 3.7 | 3.8 | 4.0 |
| constant | | | | | | |
| dissipation | GHz | 0.010 | 0.014 | 0.013 | 0.015 | 0.014 |
| factor | | | | | | |
| coefficient of | ppm/° C. | 24 | 43 | 41 | 53 | 58 |
| thermal | | | | | | |
| expansion | | | | | | |
| (α1) | | | | | | |
| Z-axis | % | 2.2 | 2.6 | 2.5 | 2.9 | 3.0 |
| expansion | | | | | | |
| percentage | | | | | | |
| thermal | ° C. | 450 | 428 | 440 | 430 | 441 |
| decomposition | | | | | | |
| temperature | | | | | | |
| UL-94 | sec | 8 | 11 | 9 | 8 | 13 |
| toughness | appear- | good | normal | good | normal | normal |
| | ance | | | | | |
| chemical | | good | normal | normal | normal | normal |
| resistance | | | | | | |
| laser drilling | | normal | good | good | good | good |
| result | | | | | | |

As shown in Table 1, by controlling the ratio of the amount of the bismaleimide to the amideimide and the reaction time, each physicochemical properties of the laminates (laminates 1 to 7) prepared by the resin composition of the present invention is satisfactory. The laminates are provided with an adhesive strength higher than 6.1 lb/inch and an outstanding toughness and chemical resistance (etchant corrosion resistance). Furthermore, the laminates prepared by the resin composition of the present invention have good size stability (coefficient of thermal expansion and z-axis expansion percentage). In addition, the z-axis expansion percentages are all less than 2.5% and they also have good electrical properties in which the dissipation factor is lower than 0.013.

On the contrary, comparative resin compositions 1′ and 2′ of which the reaction time are lower or higher than what defined in the present invention (1 hour and 5 hours, respectively) are incapable of providing a laminate whose physicochemical properties are all good. Specifically, the laminate prepared by comparative resin composition 1′ has a relatively low glass transition temperature and adhesive strength, as well as a normal degree in toughness and chemical resistance. The laminate prepared by comparative resin composition 2′ has a poor adhesive strength and a normal degree in chemical resistance. If the reaction time for the preparation of the resin composition is too short or long, the properties of the prepared laminate will be adversely affected.

Furthermore, comparative resin compositions 3′ and 4′ of which the weight ratio of the amount of the bismaleimide and amideimide are lower or higher than the suggested range as defined in the present invention are also incapable of preparing laminates whose physicochemical properties are all good. Specifically, the weight ratio of the amount of the bismaleimide and amideimide of comparative resin composition 3′ is 0.3, the glass transition temperature of the laminate prepared by comparative resin composition 3′ is extremely low (only 210° C.), the adhesive strength and size stability of the laminate is poor (z-axis expansion percentage is up to 2.9%), the evaluated toughness and chemical resistance of the laminate is a normal degree, the weight ratio of the amount of the bismaleimide and amideimide of comparative resin composition 4′ is 2.5, the size stability of the laminate prepared by comparative resin composition 4′ is extremely poor (z-axis expansion percentage is up to 3.0%), and the evaluated toughness and chemical resistance of the laminate is a normal degree. If there weight ratio of the bismaleimide and amideimide is too high or low, the prepared laminate will be adversely affected. Comparative laminates 1′ to 4′ show that the coordination of the mixing conditions of bismaleimide resin and amideimide resin, the reaction time and solvent in the resin composition of the present invention has a significant influence on the prepared laminate. The laminate prepared by the resin composition of the present invention excellent physicochemical properties (e.g., high glass transition temperature (Tg), good moisture resistance, good size stability, good flame retardance, and good chemical resistance) and excellent electrical properties (e.g., low Df, Dk). The laminate is suitable for a laser drilling process.

Furthermore, the present invention could adjust the properties of the laminate by adjusting the polymerization reaction time of the reaction solution (Example 1 to 3), the ratio of the contained resins (Example 3 and 6) or combining other additives (Example 7). As a result, the present invention is very versatile.

The above examples are used to illustrate the principle and efficacy of the present invention and show the inventive features thereof. People skilled in this field may proceed with a variety of modifications and replacements based on the disclosures and suggestions of the invention as described without departing from the principle and spirit thereof. Therefore, the scope of protection of the present invention is that as defined in the claims as appended.

What is claimed is:

1. A resin composition, which is a stable solution containing a modified bismaleimide resin and is prepared by the following steps:
(a) mixing an amideimide of the following formula A with a bismaleimide of the following formula B in a solvent to provide a reaction solution; 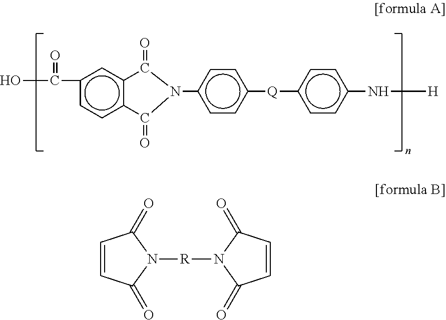
wherein,
Q is —CH₂—, —C(CH₃)₂—, —O—, —S—, —SO₂— or not existed;
n is an integer of 1 to 100;
R is —(CH₂)₂—, —(CH₂)₆—, —(CH₂)₈—, —(CH₂)₁₂—, —CH₂—C(CH₃)₂—CH₂—CH(CH₃)—CH₂—CH₂—, 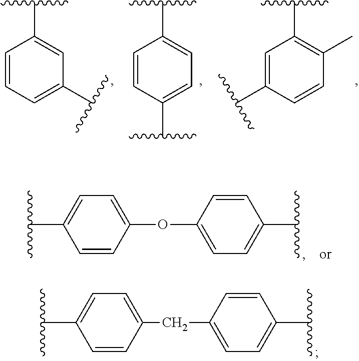
and
the weight ratio of the amount of the bismaleimide of formula B to the amideimide of formula A is about 0.4 to about 2.2;
(b) heating the reaction solution to a first temperature to carry out a reaction for 2 to 4 hours to provide a product solution; and
(c) cooling the product solution to a second temperature to substantially terminate the reaction to obtain a stable solution containing a modified bismaleimide resin,
wherein, the solvent is unreactive to the amideimide of formula A and the bismaleimide of formula B; the first temperature is higher than the temperature required for reacting the amideimide of formula A with the bismaleimide of formula B and lower than the boiling point of the solvent; the second temperature is lower than the temperature required for reacting the amideimide of formula A with the bismaleimide of formula B; and the molecular weight of the modified bismaleimide resin is about 120,000 to about 700,000.

2. The resin composition of claim 1, wherein the modified bismaleimide resin is represented by the following formula I or II: 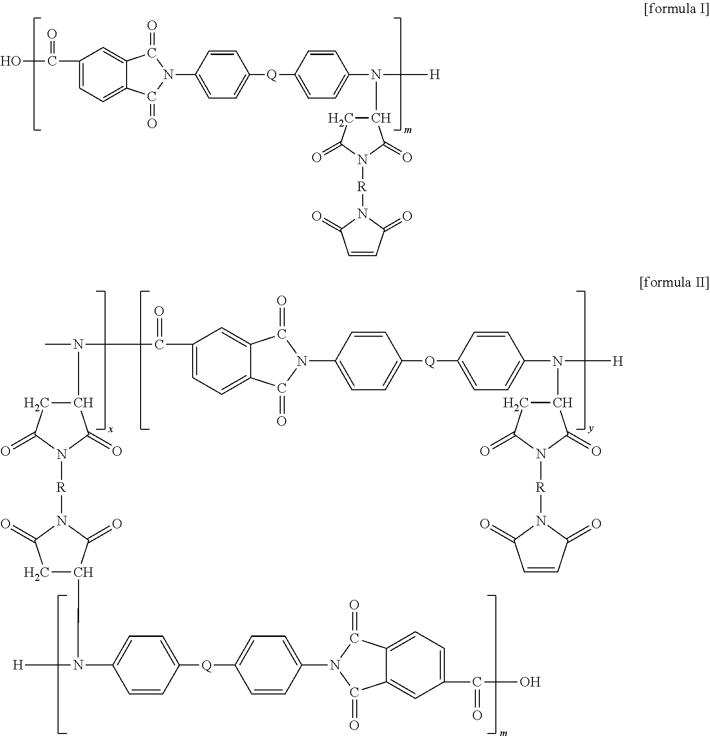
wherein, Q is —CH₂—, —C(CH₃)₂, O, S, SO₂— or not existed; R is —(CH₂)₂—, —(CH₂)₆—, —(CH₂)₈—, —(CH₂)₁₂—, —CH₂—C(CH₃)₂—CH₂—CH(CH₃)—CH₂—CH₂—, 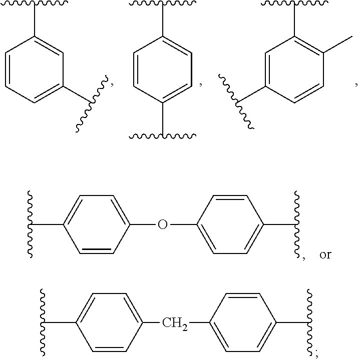
10<m<500, and x+y=m.

3. The resin composition of claim 1, wherein Q is —CH₂— and R is

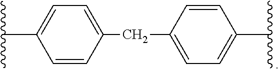 [SMILES: *c1ccc(Cc2ccc(*)cc2)cc1]

4. The resin composition of claim 2, wherein Q is —CH₂— and R is

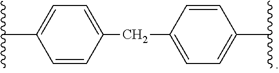 [SMILES: *c1ccc(Cc2ccc(*)cc2)cc1]

5. The resin composition of claim 1, wherein in the step (a), the weight ratio of the amount of the bismaleimide of formula B to the amideimide of formula A is about 0.8 to about 2.0.

6. The resin composition of claim 1, wherein the solvent is selected from the group consisting of cyclohexanone, acetone, butanone, methyl isobutyl ketone, N,N-dimethyl formamide (DMF), N,N-dimethyl acetamide (DMAc), N-methyl-pyrrolidone (NMP) and combinations thereof.

7. The resin composition of claim 6, wherein the solvent is a combination of N-methyl-pyrrolidone and N,N-dimethyl formamide or a combination of N-methyl-pyrrolidone and N,N-dimethyl acetamide.

8. The resin composition of claim 1, wherein the first temperature is about 100° C. to about 160° C.

9. The resin composition of claim 8, wherein the first temperature is about 120° C. to about 160° C.

10. The resin composition of claim 2, wherein the first temperature is about 100° C. to about 160° C.

11. The resin composition of claim 10, wherein the first temperature is about 120° C. to about 160° C.

12. The resin composition of claim 1, wherein the second temperature is about room temperature.

13. The resin composition of claim 2, wherein the second temperature is about room temperature.

14. The resin composition of claim 1, which further comprises an additive selected from the group consisting of a hardening promoter, a filler, a dispersing agent, a flexibilizer, a retardant and combinations thereof.

15. The resin composition of claim 14, wherein the hardening promoter is a Lewis acid or an imidazole compound.

16. The resin composition of claim 14, wherein the filler is selected from the group consisting of silica, glass powder, talcum, kaolin, pryan, mica and combinations thereof.

17. A prepreg, which is obtained by coating the resin composition of claim 1 on a substrate and drying the coated resin composition to form the prepreg on the substrate.

18. The prepreg of claim 17, wherein the substrate is a plastic substrate or a metal substrate.

19. A laminate comprising a synthetic layer and a metal layer, wherein the synthetic layer is made from the prepreg of claim 17.
